(19) United States
(12) Patent Application Publication
(10) Pub. No.: US 2002/0195646 A1
(43) Pub. Date: Dec. 26, 2002

(54) Stacked gate flash with recessed floating gate

(76) Inventor: Horng-Huei Tseng, Hsinchu (TW)

Correspondence Address: Chun M. Ng, BLAKELY, SOKOLOFF, TAYLOR & ZAFMAN LLP, Seventh Floor, 12400 Wilshire Boulevard, Los Angeles, CA, 90025-1026, US

(21) Appl. No.: 09/891,564

(22) Filed: Jun. 25, 2001

(51) Int. Cl. H01L 29/788; H01L 21/8238

(52) U.S. Cl. 257/315; 438/201; 257/316; 438/266; 257/321; 438/263

(57) ABSTRACT

A nonvolatile memory comprises a substrate having trenches formed therein, a first dielectric layer is formed on said substrate. Protruding isolations are formed in said trenches and protruding over a surface of said substrate, thereby forming cavity between thereof. A first conductive layer is formed on said first dielectric layer and in said cavity. A second dielectric layer is formed on said second conductive layer and a second conductive layer is formed on said second dielectric layer as a control gate.

The present invention relates to a semiconductor device, and more specifically, to a method of fabricating flash memories and the structure of the same.

### BACKGROUND OF THE INVENTION

Various nonvolatile memories have been disclosed in the prior art. For example, Mitchellx has proposed EPROMs with self-aligned planar array cell. In this technique, buried diffusion self-aligned to the floating gate avalanche injection MOS transistors are used for the bit lines. Cross point array technology has been disclosed. The self-aligned source and drain will allow this device to be optimized even further for programming speed. See A. T. Mitchellx, “A New Self-Aligned Planar Cell for Ultra High Density EPROMs”, IEDM, Tech. pp. 548-553, 1987”.

Flash memory is one of the segments of nonvolatile memory devices. The device includes a floating gate to storage charges and an element for electrically placing charge on and removing the charges from the floating gate. One of the applications of flash memory is BIOS for computer. Typically, the high-density nonvolatile memories can be applied as the mass storage of portable handy terminals, solid state camera and PC cards. That is because that the nonvolatile memories exhibit many advantages, such as a fast access time, low power dissipation, and robustness. Bergemont proposed another cell array for portable computing and telecommunications application, which can be seen in Bergmont et al., “Low Voltage NVG™: A New High Performance 3 V/5 V Flash Technology for Portable Computing and Telecommunications Applications”, IEEE Trans. Electron Devices, vol. ED-43, p. 1510, 1996. This cell structure is introduced for low voltage NOR Virtual Ground (NVG) flash memory having fast access time. In the flash array schematic, field oxides (FOX) are formed between cells such that a poly extension on FOX of each cell provides adequate gate coupling ratio. Bergmont also mentioned that the portable telecommunications and computing have become a major driving force in the field of integrated circuits. In the article, the access time is one of the key concerns for low voltage read operation. The NVG array uses select devices to achieve a fast access time by reducing the pre-charge time to that of a single segment rather than the full bit-line.

The formation of nonvolatile memories toward the trends of low supply power and fast access, because these requirements are necessary for the application of the mobile computing system. Flash memory needs the charges to be hold in the floating gate for a long periods of time. Therefore, the dielectric that is used for insulating the floating gate needs to be high performance. At present, the low voltage flash memory is applied with a voltage of about 3V or 5V during charging or discharging the floating gate. As known in the art, tunneling is a basic technology in charging or discharging. In order to attain high tunneling efficiency, the thickness of the dielectric between the floating gate and substrate have to be scaled down due to the supply voltage is reduced.

U.S. Pat. No. 6,180,459 to Sheu, entitled “Method for fabricating a flash memory with shallow trench isolation”, filed on Jan. 8, 1999. The prior art disclosed a method for fabricating a flash memory comprising forming a shallow trench isolation (STI) structure is also formed in the method. A further U.S. Pat. No. 6,172,395 to Chen, et al., entitled “Method of manufacture of self-aligned floating gate, flash memory cell and device manufactured thereby” and assigned to Taiwan Semiconductor Manufacturing Company (Hsin-Chu, T W).

A further prior article can be seen in U.S. Pat. No. 6,172,396. The method of forming floating gate is not a recessed type.

### SUMMARY OF THE INVENTION

The object of the present invention is to form a stacked gate flash with recessed floating gate.

A nonvolatile memory comprising a substrate having trenches formed therein, a first dielectric layer is formed on said substrate. Protruding isolations are formed in said trenches and protruding over a surface of said substrate, thereby forming cavity between thereof. A first conductive layer is formed on said first dielectric layer and in said cavity. A second dielectric layer is formed on said second conductive layer and a second conductive layer is formed on said second dielectric layer as a control gate.

A nonvolatile memory comprises a substrate having trenches formed therein. A first dielectric layer is formed on the substrate. Protruding isolations are formed in the trenches and protruding over a surface of the substrate, thereby forming cavity between thereof. A first conductive layer is conformally formed along a surface of the cavity and on the first dielectric layer. A second dielectric layer is formed on the second conductive layer and a second conductive layer formed on the second dielectric layer as a control gate.

### BRIEF DESCRIPTION OF THE DRAWINGS

The foregoing aspects and many of the attendant advantages of this invention will become more readily appreciated as the same becomes better understood by reference to the following detailed description, when taken in conjunction with the accompanying drawings, wherein:

FIG. 1 is a cross sectional view of a semiconductor wafer illustrating the steps of forming protruding isolations in a semiconductor substrate according to the present invention.

FIG. 2 is a cross sectional view of a semiconductor wafer illustrating the step of forming tunneling oxide according to the present invention.

FIG. 3 is a cross sectional view of a semiconductor wafer illustrating the step of forming floating gate according to the present invention.

FIG. 4 is cross sectional views of a semiconductor wafer illustrating the step of forming control gate according to the present invention.

FIG. 5 is a further cross sectional view of the present invention.

### DETAILED DESCRIPTION OF THE PREFERRED EMBODIMENT

The present invention proposes a novel method to fabricate a flash nonvolatile memory. In the method, the flash with recessed floating gate. The detail description will be seen as follows.

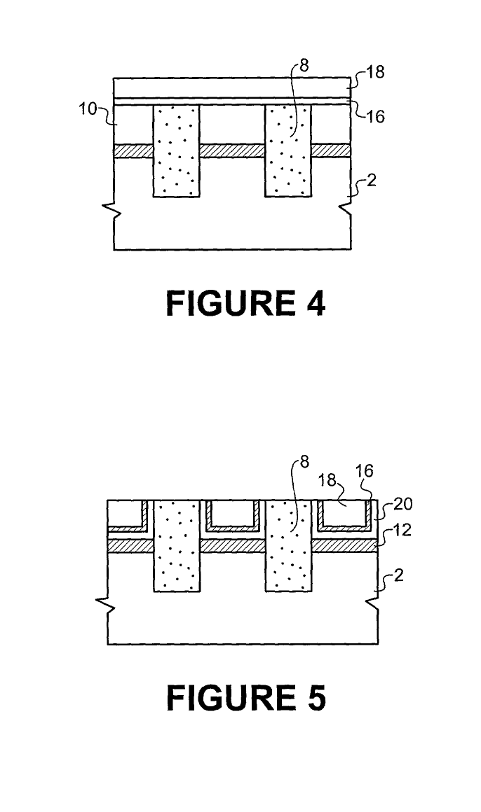

The embodiment of the structure, as shown in FIG. 4, includes a substrate having trenches formed therein. A first dielectric layer is formed on the substrate, and protruding isolations formed in the trenches and protruding over a surface of the substrate, thereby forming cavity between thereof. A first conductive layer is formed on the first dielectric layer and in the cavity. A second dielectric layer is formed on the second conductive layer and a second conductive layer is formed on the second dielectric layer as a control gate.

The processes for forming the devices are described as follows.

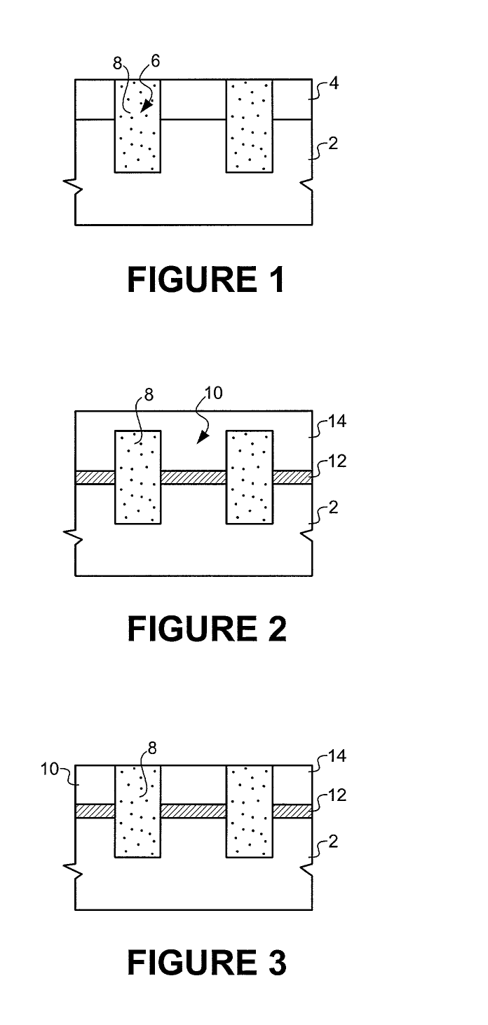

A semiconductor substrate is provided for the present invention. In a preferred embodiment, as shown in the FIG. 1, a single crystal silicon substrate 2 with a <100> or <111> crystallographic orientation is provided. A masking layer 4 is formed on the substrate 2, followed by patterning the masking layer and the substrate 2. Namely, a standard lithography and etching steps are used to etch the masking layer 4 and into the substrate 2 to a depth to form trenches 6 in the substrate 2. In this case, the dry etching uses CF₄+O₂ plasma. The thickness of the masking layer is about 500-3500 angstrom and is composed of silicon nitride. A gap filling material 6, such as oxide formed by a CVD system, which is referred to as CVD-oxide, is refilled into the trenches 6 for isolation. Preferably, the oxide layer 8 is formed at a temperature in the range of about 400 to 600 degrees centigrade. A chemical mechanical polishing (CMP) technology is used to remove the top of the CVD-oxide 8 to the surface of the masking layer 4.

Referring to FIG. 2, the masking layer 4 is removed thereby forming the raised insulator filler and forming cavity 10 between thereof. A thin tunneling dielectric layer 12 consisted of silicon oxide is formed on the substrate 2. Typically, the oxide 12 can be grown in oxygen ambient at a temperature of about 700 to 1100 degrees centigrade. Other method, such as chemical vapor deposition, can also form the oxide 12. In the embodiment, the very thin tunneling oxide 12 is formed by thermal process and does not expose in plasma, this may prevent the substrate from being damage by plasma. A conductive layer 14 such as doped polysilicon layer 6 or metal is deposited on the tunneling dielectric layer 4. Another benefit of the present invention is that the polysilicon layer 14 is chosen from doped polysilicon or in-situ polysilicon. For an embodiment, the doped polysilicon layer 14 is doped by phosphorus using a PH₃ source. Then, a portion of the conductive layer 14 is removed to have a planar surface, thereby forming recessed floating gate between insulator filler. This can be achieved by using plasma etching or CMP, as shown in FIG. 3.

Next, please turn to FIG. 4, an inter polysilicon dielectric (IPD) 16 is formed at the top of the recessed floating gate. Preferably, the ONO (oxide/nitride/oxide) or NO is used as the IPD 16. Finally, a second conductive layer 18, such as doped polysilicon layer or metal, is formed on the IPD 16 as control gate. The doped polysilicon layer 16 can be chosen from doped polysilicon or in-situ doped polysilicon. In addition, the metal or alloy layer can be used as the conductive layer 18.

Turning to FIG. 5, alternatively, a conformal conductive layer 20 may be formed along the surface of the cavity between the filler to act as the floating gate, the structure may increase the coupling ratio. The next step is to form the ONO layer along the surface of the conformal conductive layer 20. Then, the second conductive layer 18 is formed.

As will be understood by persons skilled in the art, the foregoing preferred embodiment of the present invention is illustrative of the present invention rather than limiting the present invention. Having described the invention in connection with a preferred embodiment, modification will now suggest itself to those skilled in the art. Thus, the invention is not to be limited to this embodiment, but rather the invention is intended to cover various modifications and similar arrangements included within the spirit and scope of the appended claims, the scope of which should be accorded the broadest interpretation so as to encompass all such modifications and similar structures.

While the preferred embodiment of the invention has been illustrated and described, it will be appreciated that various changes can be made therein without departing from the spirit and scope of the invention.

What is claimed is:

1. A method for manufacturing a nonvolatile memory on a substrate, said method comprising the steps of:
forming a masking dielectric layer on said substrate;
patterning said masking layer and said substrate to form trenches in said substrate;
forming a gap-filling material into said trenches and over said substrate;
removing a portion of said gap-filling material to form trench isolations;
removing said masking layer, thereby forming protruding isolations and cavity between thereof;
forming tunneling dielectric layer on the surface of said cavity;
forming a first conductive layer over a surface of said cavity and said protruding isolations;
removing a portion of said first conductive layer to have a planar surface;
forming a inter-metal dielectric layer on said first conductive layer; and
forming a second conductive layer on said inter-metal dielectric layer to act as a control gate.

2. The method of claim 1, wherein said tunneling dielectric layer comprises silicon oxide.

3. The method of claim 1, wherein said inter-metal dielectric layer comprises ONO (oxide/nitride/oxide).

4. The method of claim 1, wherein said inter-metal dielectric layer comprises ON (oxide/nitride).

5. The method of claim 1, wherein said first conductive layer, second conductive layer are selected from polysilicon, alloy or metal.

6. A method for manufacturing a nonvolatile memory on a substrate, said method comprising the steps of:
forming a masking dielectric layer on said substrate;
patterning said masking layer and said substrate to form trenches in said substrate;
forming a gap-filling material into said trenches and over said substrate;
removing a portion of said gap-filling material to form trench isolations;
removing said masking layer, thereby forming protruding isolations and cavity between thereof;
forming tunneling dielectric layer on the surface of said cavity;
forming a first conductive layer conformally along a surface of said cavity and said protruding isolations;
forming a inter-metal dielectric layer on said first conductive layer;
forming a second conductive layer on said inter-metal dielectric layer and in said cavity to act as a control gate; and
removing a portion of said first and second conductive layers to have a planar surface.

7. The method of claim 6, wherein said tunneling dielectric layer comprises silicon oxide.

8. The method of claim 6, wherein said inter-metal dielectric layer comprises ONO (oxide/nitride/oxide).

9. The method of claim 6, wherein said inter-metal dielectric layer comprises ON (oxide/nitride).

10. The method of claim 6, wherein said first conductive layer, second conductive layer are selected from polysilicon, alloy or metal.

11. A nonvolatile memory comprising:
a substrate having trenches formed therein;
a first dielectric layer formed on said substrate;
protruding isolations formed in said trenches and protruding over a surface of said substrate, thereby forming cavity between thereof;
a first conductive layer formed on said first dielectric layer and in said cavity;
a second dielectric layer formed on said second conductive layer; and
a second conductive layer formed on said second dielectric layer as a control gate.

12. The nonvolatile memory of claim 11, wherein said second dielectric comprises ONO (oxide/nitride/oxide) or ON (oxide/nitride).

13. The nonvolatile memory of claim 11, wherein said first conductive layer and said second conductive layer are selected from polysilicon, alloy or metal.

14. A nonvolatile memory comprising:
a substrate having trenches formed therein;
a first dielectric layer formed on said substrate;
protruding isolations formed in said trenches and protruding over a surface of said substrate, thereby forming cavity between thereof;
a first conductive layer conformally formed along a surface of said cavity and on said first dielectric layer;
a second dielectric layer formed on said second conductive layer; and
a second conductive layer formed on said second dielectric layer as a control gate.

15. The nonvolatile memory of claim 14, wherein said second dielectric comprises ONO (oxide/nitride/oxide) or ON (oxide/nitride).

16. The nonvolatile memory of claim 14, wherein said first conductive layer and said second conductive layer are selected from polysilicon, alloy or metal.
